(19) United States
(12) Patent Application Publication
(10) Pub. No.: US 2025/0006675 A1
(43) Pub. Date: Jan. 2, 2025

(54) SEMICONDUCTOR DEVICE, AND SEMICONDUCTOR DEVICE MANUFACTURING METHOD

(71) Applicant: Kioxia Corporation, Tokyo (JP)

(72) Inventor: Shinya ARAI, Yokohama Kanagawa (JP)

(21) Appl. No.: 18/667,435

(22) Filed: May 17, 2024

(30) Foreign Application Priority Data
Jun. 28, 2023 (JP) 2023-106063

(51) Int. Cl. H01L 23/00; H10B 80/00

(52) U.S. Cl. CPC H01L 24/05; H01L 24/03; H01L 24/08; H01L 24/80; H10B 80/00; H01L 2224/03011; H01L 2224/05557; H01L 2224/05647; H01L 2224/05693; H01L 2224/08145; H01L 2224/80895; H01L 2224/80896

(57) ABSTRACT

A semiconductor device includes a first chip and a second chip. The first chip includes a first metal pad provided on a first surface of the first chip and a first circuit connected to the first metal pad. The second chip has a second surface bonded to the first surface of the first chip. The second chip includes a second metal pad provided on the second surface and bonded to the first metal pad, and a second circuit connected to the second metal pad. The first metal pad has a first recess formed in the first surface, and a first carbon film is provided in the first recess.

### CROSS-REFERENCE TO RELATED APPLICATION(S)

This application is based upon and claims the benefit of priority from Japanese Patent Application No. 2023-106063, filed Jun. 28, 2023, the entire contents of which are incorporated herein by reference.

### FIELD

Embodiments described herein relate generally to a semiconductor device, and to a semiconductor device manufacturing method.

### BACKGROUND

In order to achieve an increase in density, effective utilization of device area, and the like, in a semiconductor device, a bonding process is performed on a semiconductor substrate having a memory cell and a semiconductor substrate having a peripheral circuit, so that metal pads provided on each semiconductor substrate are bonded together. There is concern that a void may be formed in an end portion of the bonded metal pads, as a result of which electromigration (EM) resistance or stress migration (SM) resistance decreases. Therefore, there is a demand for restricting an occurrence of such voids.

### BRIEF DESCRIPTION OF THE DRAWINGS

FIG. 1 illustrates a cross-sectional view of a structure of semiconductor device according to an embodiment at a state before a second semiconductor substrate is thinned.

FIG. 2 illustrates a cross-sectional view of a structure of the semiconductor device according to the embodiment at a state after the second semiconductor substrate is thinned.

FIG. 3 illustrates an enlarged cross-sectional view of a metal pad assembly in the semiconductor device shown in FIG. 1.

FIGS. 4A to 4C are cross-sectional diagrams to explain a manufacturing process of the semiconductor device shown in FIG. 1.

FIGS. 5A to 5C are cross-sectional diagrams to explain a manufacturing process of a conventional semiconductor device.

FIG. 6 illustrates an enlarged cross-sectional view of a modification of the metal pad assembly shown in FIG. 3.

FIG. 7 illustrates a cross-sectional view of an example of a configuration of a semiconductor chip fabricated using the semiconductor device according to the embodiment.

### DETAILED DESCRIPTION

In general, according to an embodiment, a semiconductor device includes a first chip and a second chip. The first chip includes a first metal pad provided on a first surface of the first chip and a first circuit connected to the first metal pad. The second chip has a second surface bonded to the first surface of the first chip. The second chip includes a second metal pad provided on the second surface and bonded to the first metal pad, and a second circuit connected to the second metal pad. The first metal pad has a first recess formed in the first surface, and a first carbon film is provided in the first recess.

Hereafter, a semiconductor device according to an embodiment, and a manufacturing method thereof, will be described referring to the drawings. In the embodiment, identical reference signs are allotted to essentially identical components, and a description thereof may be partially omitted. The drawings are schematic, and relationships between thicknesses and planar dimensions, ratios of thicknesses between portions, and the like, may differ from actual relationships and ratios. Unless particularly specified otherwise, terminology indicating directions such as up and down in the description indicate relative directions when a metal pad formation face of a first semiconductor substrate, to be described hereafter, is facing upward, and may differ from actual directions having a direction of gravitational acceleration as a reference.

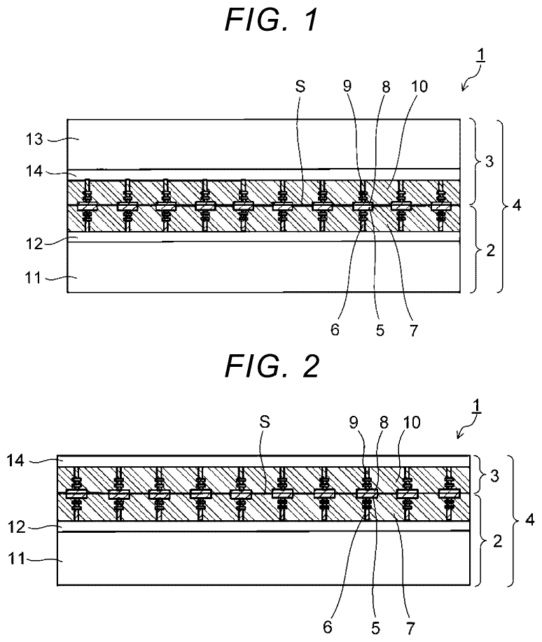

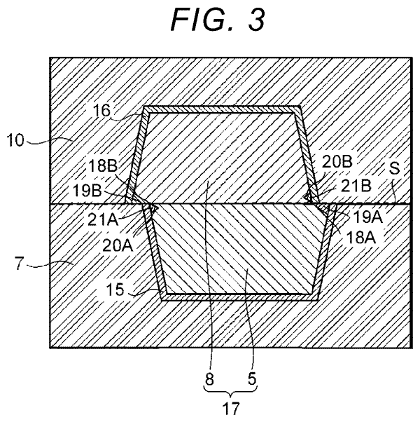

FIGS. 1 and 2 illustrate cross-sectional views of a semiconductor device 1 according to an embodiment, and FIG. 3 illustrates an enlarged cross-sectional view of a metal pad assembly in the semiconductor device 1 according to the embodiment. FIG. 1 shows the semiconductor device 1 at a state before one of two semiconductor substrates configuring a bonded substrate is thinned using back grinding or chemical processing, and FIG. 2 shows the semiconductor device 1 at a state after the one semiconductor substrate is thinned using back grinding or chemical processing.

The semiconductor device 1 shown in FIG. 1 includes a first semiconductor substrate 2 and a second semiconductor substrate 3. The first semiconductor substrate 2 and the second semiconductor substrate 3 are bonded together, forming a bonded substrate 4. That is, the semiconductor device 1 includes the bonded substrate 4. Reference sign S indicates a bonding interface of the first semiconductor substrate 2 and the second semiconductor substrate 3. The bonding interface S is shown for the sake of convenience, but as the first semiconductor substrate 2 and the second semiconductor substrate 3 are integrated, a visible joint interface may not exist. It is noted that by analyzing a cross-section of the bonded substrate 4, it can be determined that the first semiconductor substrate 2 and the second semiconductor substrate 3 are bonded together.

The first semiconductor substrate 2 has a plurality of first metal pads 5. A first wiring layer 6 is connected to at least one portion of the first metal pads 5. The first metal pad 5 and the first wiring layer 6 are embedded in a first insulating layer 7, which serves as an interlayer insulating film. The plurality of first metal pads 5 are disposed in such a way that surfaces thereof are exposed in a surface of the first insulating layer 7. The second semiconductor substrate 3 has a plurality of second metal pads 8. A second wiring layer 9 is connected to at least one portion of the second metal pads 8. The second metal pad 8 and the second wiring layer 9 are embedded in a second insulating layer 10, which serves as an interlayer insulating film. The plurality of second metal pads 8 are disposed in such a way that surfaces thereof are exposed in a surface of the second insulating layer 10. FIGS. 1 and 2 show a state in which the first and second wiring layers 6 and 9 are connected to the first and second metal pads 5 and 8. That is, FIGS. 1 and 2 show the first and second metal pads 5 and 8 to which the first and second wiring layers 6 and 9 are connected. One portion of the first and second metal pads 5 and 8 may be dummy pads that are not connected to any wiring layer. Also, the first and second wiring layers 6 and 9 may include via plugs or the like, as will be described hereafter.

The first semiconductor substrate 2 has a first circuit region 12 provided with a first circuit (not shown) including, for example, peripheral circuits (not shown) such as a transistor, such as a CMOS, and a passive element and a wiring layer that connects the peripheral circuits and at least one portion of the first metal pads 5. The first circuit region 12 is provided on a semiconductor substrate main body 11 of the first semiconductor substrate 2. The second semiconductor substrate 3 has a second circuit region 14 provided with a second circuit (not shown) including, for example, an image array including a plurality of image sensing elements or a memory cell array including a plurality of memory cells, a source line, a plurality of bit lines, a wiring layer connected to at least one portion of the second metal pads 8, and the like. The second circuit region 14 is provided below a semiconductor substrate main body 13 of the second semiconductor substrate 3 (i.e., on the semiconductor substrate main body 13 in a semiconductor device manufacturing process). The first semiconductor substrate 2 configures, for example, a control circuit chip, and the second semiconductor substrate 3 configures, for example, an array chip.

The second semiconductor substrate 3 may be thinned by carrying out back grinding or chemical processing on the bonded substrate 4 in such a way that at least the second circuit region 14 remains, as shown in FIG. 2. At this time, the semiconductor substrate main body 13 of the second semiconductor substrate 3 may, but need not, remain. In the semiconductor device 1 shown in FIG. 2, the first semiconductor substrate 2 having the first metal pad 5 and the first circuit region 12 forms a first device component. The second semiconductor substrate 3 having the second metal pad 8 and the second circuit region 14 and from which the semiconductor substrate main body 13 is eliminated, or in other words, a remaining portion of the second semiconductor substrate 3 from which the semiconductor substrate main body 13 is eliminated, forms a second device component. Furthermore, the first semiconductor substrate 2 and the second semiconductor substrate 3, which have a wafer form when bonded together, correspond respectively to a first chip component and a second chip component that include a plurality of constituent units of chips fabricated using the first semiconductor substrate 2 and the second semiconductor substrate 3.

The first metal pad 5 and the second metal pad 8 are embedded in the first insulating layer 7 and the second insulating layer 10, respectively, with barrier metal layers 15 and 16 respectively, as shown in FIG. 3. Generally, titanium, a titanium alloy, titanium nitride, tantalum, tantalum alloy, tantalum nitride, or the like, is used as the barrier metal layers 15 and 16. The first metal pad 5 and the second metal pad 8 are joined (e.g., bonded together) in a bonding process to be described hereafter, configuring an assembly 17, as shown in FIG. 3. Although omitted in FIG. 3, the first semiconductor substrate 2 includes, as heretofore described, the first wiring layer 6, which is connected to at least one portion of the first metal pads 5, and the first circuit region 12 having a first circuit including peripheral circuits such as a transistor, such as a CMOS, and a passive element, a wiring layer, and the like. The second semiconductor substrate 3 includes, as heretofore described, the second wiring layer 9, which is connected to at least one portion of the second metal pads 8, and the second circuit region 14 having a second circuit including an image array, a memory cell array, a wiring layer, and the like.

The first metal pad 5 and the second metal pad 8 are disposed in such a way as to be exposed in surfaces of the first insulating layer 7 and the second insulating layer 10, respectively, and contribute to a coupling of the first semiconductor substrate 2 and the second semiconductor substrate 3. The first insulating layer 7 and the second insulating layer 10 also contribute to a coupling of the first semiconductor substrate 2 and the second semiconductor substrate 3. Although an inorganic insulating material such as silicon oxide (SiO), silicon nitride (SiN), silicon carbide (Sic), silicon oxynitride (SiON), or silicon carbonitride is used in the first and second insulating layers 7 and 10, the first and second insulating layers 7 and 10 may also be formed of an insulating material other than these materials. The first and second insulating layers 7 and 10 each may be of a structure such that one or more layers are stacked. Although a metal material, such as copper or a copper alloy, having a thermal expansion coefficient higher than that of the inorganic insulating material used in the first and second insulating layers 7 and 10 is used in the first and second metal pads 5 and 8, the first and second metal pads 5 and 8 may also be formed of a metal material other than these materials.

A surface of the first metal pad 5 exposed in the bonding surface of the first semiconductor substrate 2 and a surface of the second metal pad 8 exposed in the bonding surface of the second semiconductor substrate 3 are directly joined using an elemental diffusion between metals, a van der Waals force, metal bonding caused by volumetric expansion (i.e., thermal expansion), and the like. Furthermore, a surface of the first insulating layer 7 exposed in the bonding surface of the first semiconductor substrate 2 and a surface of the second insulating layer 10 exposed in the bonding surface of the second semiconductor substrate 3 are directly joined using an elemental diffusion between insulators, a van der Waals force, a chemical reaction such as dehydration condensation or polymerization, and the like. Because of such manners of joining, the first semiconductor substrate 2 and the second semiconductor substrate 3 are bonded together.

For example, when a silicon dioxide film or the like is used for the first and second insulating layers 7 and 10, the surfaces of the first and second insulating layers 7 and 10 are activated by a plasma of nitrogen (N₂), oxygen (O₂), argon (Ar), or the like. Next, the surfaces of the first and second insulating layers 7 and 10 are rinsed using deionized water, providing the surfaces with a hydroxy group (a siloxane bond). Then, the first semiconductor substrate 2 and the second semiconductor substrate 3 are positioned one on the other. At this time, the first semiconductor substrate 2 and the second semiconductor substrate 3 are joined by a hydrogen bond between the surface of the first insulating layer 7 and the surface of the second insulating layer 10. Subsequently, metal bonding between the copper pads is caused by the thermal expansion of copper by implementing an annealing process in the region of several hours at a temperature in the region of, for example, 300 to 400° C., together with which a covalent bonding of the silicon dioxide films is caused by dehydration condensation. Because of such processes, the first semiconductor substrate 2 and the second semiconductor substrate 3 can be strongly bonded together.

In the assembly 17 of the first metal pad 5 and the second metal pad 8, at least one of the first metal pad 5 and the second metal pad 8 has recesses 18 (18A or 18B) and 20 (20A or 20B) provided in the bonding interface S of the first semiconductor substrate 2 and the second semiconductor substrate 3, and carbon films 19 (19A or 19B) and 21 (21A or 21B) that fill these kinds of recesses 18 and 20 are formed. By filling the recesses 18 and 20 provided in the bonding interface S of the first semiconductor substrate 2 and the second semiconductor substrate 3 with the carbon films 19 and 21, thereby eliminating spaces of the recesses 18 and 20, a decrease in EM resistance and SM resistance of the semiconductor device 1 can be prevented. At this time, by filling the recesses 18 and 20 with the carbon films 19 and 21, the EM resistance and the SM resistance can increase due to the elimination of the spaces, without leading to a deterioration of electrical properties of the semiconductor device 1, a deterioration of properties due to a foreign object such as a metal, or the like. A state in which a recess in the bonding interface S and a carbon film filling the recess are provided in both the first metal pad 5 and the second metal pad 8 is shown in FIG. 3, but it is sufficient that a recess and a carbon film are provided in at least one of the first metal pad 5 and the second metal pad 8.

The recesses 18 and 20 provided in the bonding interface S will be described in detail hereafter. In the assembly 17 of the first metal pad 5 and the second metal pad 8, the first metal pad 5 has the first recess 18A in at least one portion of a region deviating (, which may be referred to as offsetting) from the second metal pad 8 to which the first metal pad 5 is joined, and the second metal pad 8 has the first recess 18B in at least one portion of a region deviating from the first metal pad 5 to which the second metal pad 8 is joined. The assembly 17 has the first carbon films 19A and 19B that fill the first recess 18A and 18B. That is, the first metal pad 5 and the second metal pad 8 have the first carbon films 19A and 19B that fill the first recesses 18A and 18B provided in at least one portion of regions deviating from the metal pads 8 and 5 to which the metal pads 5 and 8 are joined.

Furthermore, in the assembly 17 of the first metal pad 5 and the second metal pad 8, the first metal pad 5 has the second recess 20A in at least one portion of a region opposing the second metal pad 8 to which the first metal pad 5 is joined, and the second metal pad 8 has the second recess 20B in at least one portion of a region opposing the first metal pad 5 to which the second metal pad 8 is joined. The assembly 17 has the second carbon films 21A and 21B that fill the second recess 20A and 20B. That is, the first metal pad 5 and the second metal pad 8 have the second carbon films 21A and 21B that fill the second recesses 20A and 20B provided in at least one portion of regions opposing the metal pads 8 and 5 to which the metal pads 5 and 8 are joined.

As heretofore described, the first carbon films 19A and 19B fill the first recesses 18A and 18B provided in at least one portion of regions of the first metal pad 5 and the second metal pad 8 deviating from the metal pads 8 and 5 to which the metal pads 5 and 8 are joined, whereby spaces of the first recesses 18A and 18B are eliminated, because of which a decrease in the EM resistance and the SM resistance of the semiconductor device 1 can be prevented. Furthermore, in addition to eliminating spaces of the first recesses 18A and 18B provided in regions of the metal pads 5 and 8 deviating from the metal pads and 5 to which the metal pads 5 and 8 are joined, the second carbon films 21A and 21B fill the second recesses 20A and 20B provided in at least one portion of regions of the first metal pad 5 and the second metal pad 8 opposing the metal pads 8 and 5 to which the metal pads 5 and 8 are joined, whereby spaces of the second recesses 20A and 20B are eliminated, because of which a decrease in the EM resistance and the SM resistance of the semiconductor device 1 can be further prevented. Filling the second recesses 20A and 20B provided in at least one portion of regions opposing the metal pads 8 and 5 to which the metal pads 5 and 8 are joined with the second carbon films 21A and 21B is particularly effective in increasing the EM resistance and the SM resistance. Although filling the second recess 20 provided in opposing regions of the metal pads 5 and 8 with another material after bonding is difficult, the second recess 20 can be reliably eliminated by filling the second recess 20 with the carbon film 21 when carrying out the bonding process. Because of this, the EM resistance and the SM resistance can be caused to increase.

Here, in the assembly 17 of the first metal pad 5 and the second metal pad 8, copper of the first metal pad 5 and copper of the second metal pad 8 are integrated, and a border between the first metal pad 5 and the second metal pad 8 may be difficult to observe. However, a bonding can be observed by a distortion of a bonded form of the metal pad 5 and the metal pad 8 caused by a bonding position deviation, or a positional deviation of the barrier metal layers 15 and 16 (e.g., a non-continuous place when seen in a side view). Also, when the metal pad 5 and the metal pad 8 are formed using a damascene method, each side surface has a tapered form. Because of this, a form of a vertical cross-section of a portion in which the metal pad 5 and the metal pad 8 are bonded together is a non-rectangular form rather than a side wall being of a linear form. Furthermore, when the metal pad 5 and the metal pad 8 are bonded together, a structure in which a bottom surface, side surfaces, and a top surface of the metal pad 5 and the metal pad 8, which are formed of copper, are covered by a barrier metal, is formed. As opposed to this, in a general wiring layer in which copper is used, an insulating layer (silicon nitride, silicon carbonitride, or the like) having a function of preventing copper oxidation is provided on the top face of the copper, and no barrier metal is provided. This means that a distinction from a general wiring layer can be made even when no bonding position deviation occurs.

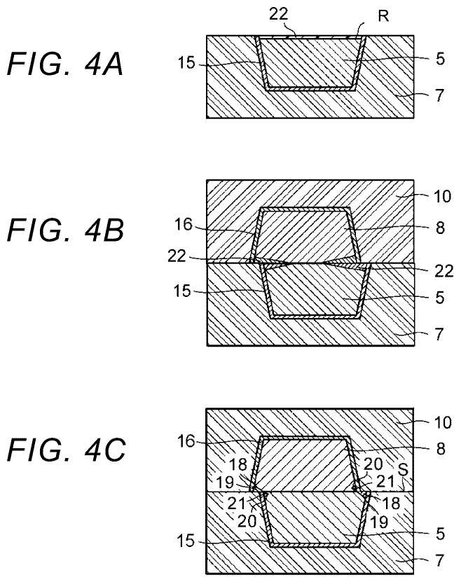

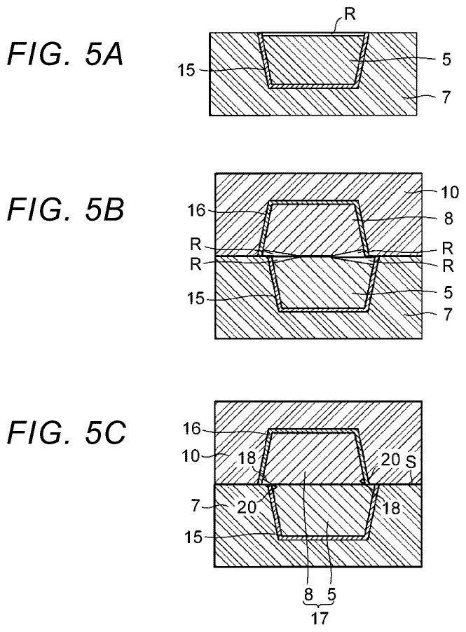

The first recess 18 provided in regions of the first and second metal pads 5 and 8 deviating from the metal pads 8 and 5 to which the metal pads 5 and 8 are joined, and the second recess 20 provided in regions of the first and second metal pads 5 and 8 opposing the metal pads 8 and 5 to which the metal pads 5 and 8 are joined, are formed during the bonding process of the first semiconductor substrate 2 and the second semiconductor substrate 3. A manufacturing process (bonding process) of the semiconductor device 1 according to the embodiment is shown in FIGS. 4A to 4C, and as a comparison to this, a manufacturing process (bonding process) of a conventional semiconductor device is shown in FIGS. 5A to 5C. The surfaces of the first and second metal pads 5 and 8 are flattened during a process prior to the bonding process of the first semiconductor substrate 2 and the second semiconductor substrate 3. Specifically, the surfaces of the first and second semiconductor substrates 2 and 3 before bonding are flattened by processing using, for example, a chemical mechanical polishing (CMP). At this time, a depression R is formed in the surfaces of the metal pads 5 and 8 by the surfaces of the metal pads 5 and 8 being depressed in the region of 3 nm on one side, as shown in FIG. 5A. Although only the metal pad 5 is shown in FIG. 5A, the same applies to the metal pad 8.

After these kinds of metal pad 5 and 8 whose surfaces are depressed in the region of 3 nm on one side are positioned together, the metal pads 5 and 8 formed of, for example, copper thermally expand when annealed at a temperature in the region of 300 to 400° C., as shown in FIG. 5B, and joining occurs from vicinities of central portions of the upper and lower metal pads 5 and 8. On vicinities of the central portions of the upper and lower metal pads 5 and 8 joining, end portion sides of the metal pads 5 and 8 deform in such a way as to recede. On the bonding process caused by annealing further proceeding, the joining in vicinities of the central portions of the upper and lower metal pads 5 and 8 advances, and the joined region in the vicinities of the central portions of the upper and lower metal pads 5 and 8 gradually spreads to the end portion sides. However, joining completely to the end portions of the metal pads 5 and 8 is difficult, and the depression R is likely to remain in outer peripheral side end portions of the metal pads 5 and 8, as shown in FIG. 5B.

Even when widening the joined region of the metal pads 5 and 8 to the end portion sides, it is difficult for the depression R in the outer peripheral side end portions of the metal pads 5 and 8 to be completely eliminated. Because of this, the first recess 18 remains in a region in outer peripheral regions of the first metal pad 5 and the second metal pad 8 deviating from the metal pads 8 and 5 to which the metal pads 5 and 8 are joined, as shown in FIG. 5C. Similarly, the second recess 20 remains in a region in outer peripheral regions of the first metal pad 5 and the second metal pad 8 opposing the metal pads 8 and 5 to which the metal pads 5 and 8 are joined. As previously mentioned, these kinds of recess 18 and 20 remaining cause the EM resistance and the SM resistance of the semiconductor device 1 to decrease. A recess in the bonding interface S not being limited to the outer peripheral regions of the metal pads 5 and 8, a recess may also, depending on a bonding state or the like, be formed in vicinities of centers of the metal pads 5 and 8.

To address such an issue, in the manufacturing process of the semiconductor device 1 according to the embodiment, a carbon film 22 is formed in the depression R in the surface of the metal pad 5 formed by a CMP processing, as shown in FIG. 4A. An organic film having carbon as a main element may be used instead of the carbon film 22. An organic film used here, not being limited to an organic film formed on the metal pad 5, may be an organic film remaining in a rinsing process or the like after the CMP. The carbon film (or organic film) 22 is formed in the depression R in the surface of the metal pad 5. Only the first metal pad 5 and first insulating layer 7 provided in the first semiconductor substrate 2 are shown in FIG. 4A, but in actual, the second metal pad 8 and second insulating layer 10 provided in the second semiconductor substrate 3 are disposed in such a way as to oppose the first metal pad 5. This means that the carbon film (or organic film) 22 may also be formed in a depression in the surface of the second metal pad 8. It is sufficient that the carbon film (or organic film) 22 is formed in the depression R in the surface of at least one of the first metal pad 5 and the second metal pad 8.

Next, as shown in FIGS. 4B and 4C, the first metal pad 5 and the second metal pad 8 are positioned across the carbon film (or organic film) 22 formed on the surface of at least one of the first metal pad 5 and the second metal pad 8, after which the first semiconductor substrate 2, in which the surfaces of the first metal pad 5 and the first insulating layer 7 are exposed, and the second semiconductor substrate 3, in which the surfaces of the second metal pad 8 and the second insulating layer 10 are exposed, are bonded together. The bonding process is implemented under known conditions. For example, the first semiconductor substrate 2 and the second semiconductor substrate 3 are bonded together using mechanical pressure. By so doing, the first insulating layer 7 and the second insulating layer 10 are joined and integrated. Next, an annealing process is implemented on the first semiconductor substrate 2 and the second semiconductor substrate 3 for several hours at a temperature in a range of, for example, 300 to 400° C. As a result, the first metal pad 5 and the second metal pad 8 are joined, and the first and second metal pads 5 and 8 are electrically connected, and integrated.

At this time, as the vicinities of the central portions of the metal pads 5 and 8 are joined, the carbon film (or organic film) 22 formed on the surface of at least one of the first metal pad 5 and the second metal pad 8 exists in an outer peripheral portion of the central joined portion, as shown in FIG. 4B. Of these, the carbon film 22 formed on the pad surface exists unchanged as the carbon film 22 in a depression in the outer peripheral portion of the central joined portion. Also, the organic film formed on the pad surface decomposes due to the annealing temperature, and exists as the carbon film 22 in a depression in the outer peripheral portion of the central joined portion after decomposing. Hydrogen, oxygen, or the like generated by the decomposition of the organic film vaporizes due to the annealing temperature, because of which there is no adverse effect on the semiconductor device 1.

Subsequently, as shown in FIG. 4C, the first recess 18 provided in at least one portion of regions of the metal pads 5 and 8 deviating from the metal pads 8 and 5 to which the metal pads 5 and 8 are joined is filled with the first carbon film 19. Similarly, the second recess 20 provided in at least one portion of regions of the metal pads 5 and 8 opposing the metal pads 8 and 5 to which the metal pads 5 and 8 are joined is filled with the second carbon film 21. By doing so, the bonded substrate 4 configuring the semiconductor device 1 according to the embodiment, that is, the bonded substrate 4 configured with the first semiconductor substrate 2 and the second semiconductor substrate 3, is fabricated. As the first carbon film 19 and the second carbon film 21 occupy spaces formed by the first recess 18 and the second recess 20, a decrease in the EM resistance and the SM resistance caused by a space existing in a vicinity of the bonding interface S of the first semiconductor substrate 2 and the second semiconductor substrate 3 can be prevented. That is, the semiconductor device 1 including the bonded substrate 4 with excellent EM resistance and SM resistance can be provided.

FIG. 3 shows a case in which the first metal pad 5 and the second metal pad 8 have essentially the same form and the same area. In such a case, joining the first metal pad 5 and the second metal pad 8 such that positions thereof coincide exactly is difficult, and the first metal pad 5 and the second metal pad 8 being joined in a state in which central lines thereof deviate slightly, as shown in FIG. 3, is common. This means that when the first metal pad 5 and the second metal pad 8 have essentially the same form, the first recesses 18A and 18B provided in at least one portion of regions of the metal pads 5 and 8 deviating from the metal pads 8 and 5 to which the metal pads 5 and 8 are joined are filled with the first carbon films 19A and 19B, as shown in FIG. 3. Furthermore, the second recesses 20A and 20B provided in at least one portion of regions of the metal pads 5 and 8 opposing the metal pads 8 and 5 to which the metal pads 5 and 8 are joined are filled with the second carbon films 21A and 21B.

It is noted that depending on differences in the areas or forms of the first metal pad 5 and the second metal pad 8, and furthermore, a way in which the first metal pad 5 and the second metal pad 8 are positioned one on the other, the first recess 18 and the second recess 20 may be formed in only one of the first metal pad 5 and the second metal pad 8. Consequently, it is sufficient that the first recess 18 and the first carbon film 19 filling an interior of the first recess 18 are provided in at least one portion of a region of at least one of the first metal pad 5 and the second metal pad 8 deviating from the metal pad 8 or 5 to which the metal pad 5 or 8 is joined. Similarly, it is sufficient that the second recess 20 and the second carbon film 21 filling an interior of the second recess 20 are provided in at least one portion of a region of at least one of the first metal pad 5 and the second metal pad 8 opposing the metal pad 8 or 5 to which the metal pad 5 or 8 is joined.

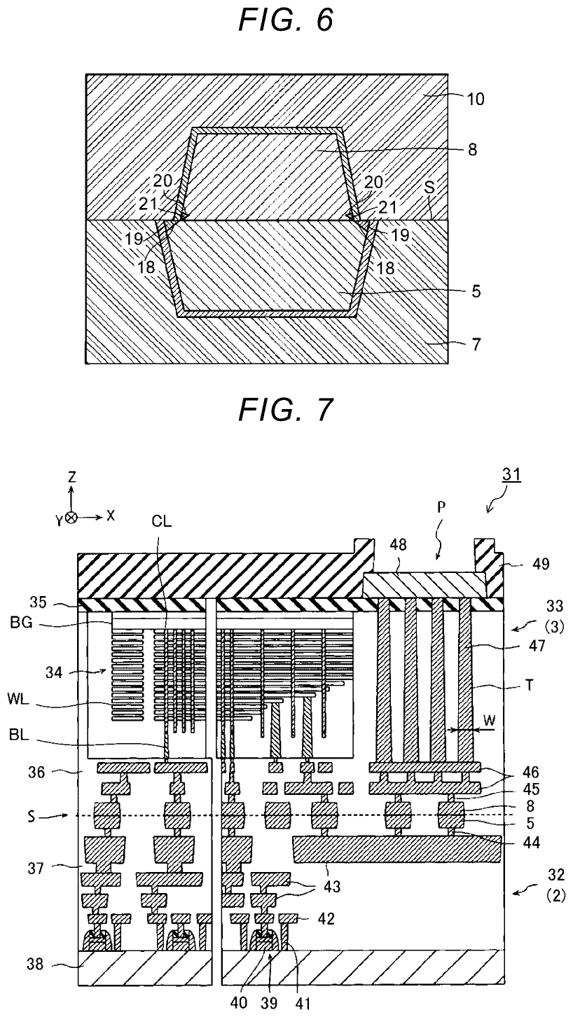

Furthermore, when the first metal pad 5 has an area greater than that of the second metal pad 8, or when the reverse is true, the metal pads 5 and 8 may be positioned one on the other in such a way that a whole of the second metal pad 8 is positioned in an interior of the first metal pad 5, as shown in, for example, FIG. 6. FIG. 6 illustrates an enlarged cross-sectional view of a modification of a metal pad assembly. The assembly shown in FIG. 6 is such that only the first metal pad 5 has the first recess 18 provided in at least one portion of a region deviating from the metal pad 8 to which the metal pad 5 is joined, and the first carbon film 19 filling the interior of the first recess 18. Similarly, only the second metal pad 8 has the second recess 20 provided in at least one portion of a region opposing the metal pad 5 to which the metal pad 8 is joined, and the second carbon film 21 filling the interior of the second recess 20. In such a case, a carbon film or an organic film (reference sign 22 in FIG. 4) may be formed on only the surface of the second metal pad 8, whose area is smaller in, for example, FIG. 6, and a process of filling the second recess 20 with the second carbon film 21 may be implemented with priority. In this way, various combinations of the first recess 18 and first carbon film 19 and the second recess 20 and second carbon film 21 may be applied in accordance with areas and forms of the first metal pad 5 and the second metal pad 8, and furthermore, in accordance with the way in which the first metal pad 5 and the second metal pad 8 are positioned one on the other, and the like.

Next, one example of a semiconductor chip fabricated using the semiconductor device 1 according to the embodiment will be described, referring to FIG. 7. FIG. 7 illustrates a cross-sectional view of an example of a configuration of a semiconductor chip. A semiconductor chip 31 shown in FIG. 7 includes a control circuit chip 32, which is formed from one portion of the first semiconductor substrate 2 having a first circuit region, and an array chip 33, which is formed from one portion of the second semiconductor substrate 3 having a second circuit region. This kind of semiconductor chip 31 is fabricated by the semiconductor device 1 according to the embodiment being singulated into a chip by being cut along each chip region. The control circuit chip 32 and the array chip 33 are bonded together.

The array chip 33 includes a memory cell array 34 that includes a plurality of memory cells, an insulating film 35 on the memory cell array 34, and an interlayer insulating film 36 under the memory cell array 34. The control circuit chip 32 is provided below the array chip 33. Reference sign indicates a bonding interface of the array chip 33 and the control circuit chip 32. The control circuit chip 32 includes an interlayer insulating film 37 and a substrate 38 under the interlayer insulating film 37. The substrate 38 is a semiconductor substrate such as a silicon substrate. The insulating films 35, 36, and 37 are silicon oxide films, silicon nitride films, silicon oxynitride films, or the like, and each may be of a structure such that one kind or a plurality of materials are mixed or stacked.

FIG. 7 shows an X direction and a Y direction, which are parallel to a surface of the substrate 38 and perpendicular to each other, and a Z direction that is perpendicular to the surface of the substrate 38. Herein, a +Z direction is treated as an upward direction, and a −Z direction is treated as a downward direction. For example, the array chip 33 is formed such that the memory cell array 34 functioning as a second circuit region is positioned above the substrate 38, and the substrate 38 is positioned below the memory cell array 34. The −Z direction may, but need not, coincide with a direction of gravitational force.

The array chip 33 includes a plurality of word lines WL and a select gate line of which a depiction is omitted as electrode layers in the memory cell array 34. A stepped structure portion of the memory cell array 34 is shown in an X direction central portion of FIG. 7. A columnar portion CL penetrating the word line WL is formed such that one end is electrically connected to a source line BG, while another end is electrically connected to a bit line BL, and a memory cell is formed in a portion in which the columnar portion CL and the word line WL intersect.

The control circuit chip 32 includes a plurality of transistors 39 that function as one portion of the first circuit region. Each transistor 39 includes a gate electrode 40, which is provided across a gate insulating film on the substrate 38, and an unshown source diffusion layer and drain diffusion layer provided in the substrate 38. The control circuit chip 32 further includes a plurality of plugs 41, which are provided above the source diffusion layers or the drain diffusion layers of the transistors 39 and above the gate electrode 40, a wiring layer 42, which is provided above the plugs 41 and includes a plurality of wires, and a wiring layer 43, which is provided above the wiring layer 42 and includes a plurality of wires. The control circuit chip 32 further includes a plurality of via plugs 44, which are provided above the wiring layer 43, and the plurality of metal pads 5, which are provided above the via plugs 44 in the insulating film 37. The heretofore described kind of control circuit chip 32 functions as a control circuit (a logic circuit) that controls the array chip 23.

The array chip 33 includes the plurality of metal pads 8, which are provided above the metal pads 5 in the insulating film 36, a plurality of via plugs 45, which are provided above the metal pads 8, and a wiring layer 46, which is provided above the via plugs 45 and includes a plurality of wires. Each word line WL and each bit line BL is electrically connected to a corresponding wire in the wiring layer 46. The array chip 33 further includes a via plug 47, which is provided in the insulating film 36 and the insulating film 35 and is provided above the wiring layer 46, and a metal pad 48, which is provided above the insulating film 35 and above the via plug 47.

The metal pad 48 functions as an external connection pad of the semiconductor chip 31 shown in FIG. 7, and can be connected to a mounting substrate or another device via a bonding wire, a solder ball, a metal bump, or the like. The array chip 33 further includes a passivation film 49 formed above the insulating film 35 and the metal pad 48. The passivation film 49 has an aperture portion P in which an upper face of the metal pad 48 is exposed, and the portion P is used, for example, for aperture connecting a bonding wire or the like to the metal pad 48.

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first chip including a first metal pad provided on a first surface of the first chip and a first circuit connected to the first metal pad; and
a second chip having a second surface bonded to the first surface of the first chip, the second chip including a second metal pad provided on the second surface and bonded to the first metal pad, and a second circuit connected to the second metal pad,
wherein the first metal pad has a first recess formed in the first surface, and a first carbon film is provided in the first recess.

2. The semiconductor device according to claim 1, wherein the first chip includes a first substrate on which the first metal pad and the first circuit are provided.

3. The semiconductor device according to claim 1, wherein
one of the first circuit and the second circuit includes a memory cell array, which is connected to a corresponding one of the first metal pad and the second metal pad via a wiring, and
the other of the first circuit and the second circuit includes a control circuit configured to control the memory cell array, the control circuit including a transistor, which is connected to the other of the first metal pad and the second metal pad via a wiring.

4. The semiconductor device according to claim 1, wherein the first carbon film is provided along an outer periphery of the first metal pad on the first surface.

5. The semiconductor device according to claim 1, wherein a surface area of the first metal pad on the first surface and a surface area of the second metal pad on the second surface are substantially the same, and the first metal pad and the second metal pad are bonded with an offset from each other in a direction that is parallel to the first and second surfaces.

6. The semiconductor device according to claim 5, wherein at least a part of the first carbon film on the first surface is not in contact with the second metal pad.

7. The semiconductor device according to claim 6, wherein at least a part of the first carbon film on the first surface is in contact with the second metal pad.

8. The semiconductor device according to claim 5, wherein the second metal pad has a second recess formed in the second surface, and a second carbon film is provided in the second recess.

9. The semiconductor device according to claim 8, wherein
at least a part of the second carbon film on the second surface is not in contact with the first metal pad, and
at least a part of the second carbon film on the second surface is in contact with the first metal pad.

10. The semiconductor device according to claim 1, wherein a surface area of the first metal pad on the first surface and a surface area of the second metal pad on the second surface are different, and a region of one of the first metal pad on the first surface and the second metal pad on the second surface is entirely overlapped by a region of the other.

11. The semiconductor device according to claim 10, wherein
the region of the second metal pad on the second surface is entirely overlapped by the region of the first metal pad on the first surface, and
at least a part of the first carbon film on the first surface is not in contact with the second metal pad.

12. The semiconductor device according to claim 10, wherein
the region of the first metal pad on the first surface is entirely overlapped by the region of the second metal pad on the second surface, and
an entire part of the first carbon film on the first surface is in contact with the second metal pad.

13. The semiconductor device according to claim 10, wherein the second metal pad has a second recess formed in the second surface, and a second carbon film is provided in the second recess.

14. The semiconductor device according to claim 1, wherein
the first chip further includes a first insulating layer in which the first metal pad is formed, the first surface being formed with the first insulating layer, the first metal pad, and the first carbon film, and
the second chip further includes a second insulating layer in which the second metal pad is formed, the second surface being formed with the second insulating layer and the second metal pad.

15. The semiconductor device according to claim 14, wherein
a thermal expansion coefficient of a material of the first metal pad is higher than a thermal expansion coefficient of a material of the first insulating layer and higher than a thermal expansion coefficient of a material of the second insulating layer, and
a thermal expansion coefficient of a material of the second metal pad is higher than the thermal expansion coefficient of the material of the first insulating layer and higher than the thermal expansion coefficient of the material of the second insulating layer.

16. The semiconductor device according to claim 14, wherein the first metal pad and the second metal pad are each formed of copper or a copper alloy.

17. A method for manufacturing a semiconductor device, comprising:
preparing a first chip component having a first semiconductor substrate, a first metal pad exposed on a first surface of the first chip component, and a first circuit connected to the first metal pad;
preparing a second chip component having a second semiconductor substrate, a second metal pad exposed on a second surface of the second chip component, and a second circuit connected to the second metal pad;
forming a carbon or organic film on the first metal pad;
after said forming the carbon or organic film, placing the first chip component and the second chip component such that the first surface contacts the second surface and the first metal pad faces the second metal pad via the carbon or organic film; and
bonding the first metal pad and the second metal pad with heat.

18. The method according to claim 17, wherein during said bonding, a carbon film derived from the carbon or organic film is formed in a recess that is formed along an outer periphery of at least one of the first metal pad and the second metal pad.

19. The method according to claim 17, further comprising:
performing a chemical mechanical polishing (CMP) on the first surface of the prepared first chip component, an exposed surface of the first metal pad being recessed as a result of the CMP,
wherein the carbon or organic film is formed on the recessed exposed surface of the first metal pad.

20. The method according to claim 19, further comprising:
after said performing the CMP, rinsing the first surface of the prepared first chip component,
wherein a residual material after said rinsing is formed as the carbon or organic film.
